(19) United States
(12) Patent Application Publication
(10) Pub. No.: US 2024/0038825 A1
(43) Pub. Date: Feb. 1, 2024

(54) SEMICONDUCTOR LIGHT EMITTING DEVICE FOR A DISPLAY PIXEL AND A DISPLAY DEVICE INCLUDING THE SAME

(71) Applicant: LG ELECTRONICS INC., Seoul (KR)

(72) Inventors: Byoungkwon CHO, Seoul (KR); Wonseok CHOI, Seoul (KR); Jeonghyo KWON, Seoul (KR); Sungmin PARK, Seoul (KR)

(73) Assignee: LG ELECTRONICS INC., Seoul (KR)

(21) Appl. No.: 18/227,788

(22) Filed: Jul. 28, 2023

(30) Foreign Application Priority Data
Jul. 29, 2022 (WO) PCT/KR2022/011240

(51) Int. Cl. H01L 27/15; G09G 3/32; H01L 33/24; H01L 33/44; H01L 33/40

(52) U.S. Cl. CPC H01L 27/156; G09G 3/32; H01L 33/24; H01L 33/44; H01L 33/405; G09G 2300/0842

(57) ABSTRACT

The embodiment relates to a semiconductor light emitting device for a display pixel and a display device including the same. A semiconductor light emitting device for a display pixel according to an embodiment can include a light emitting structure including a first conductivity type semiconductor layer, a second conductivity type semiconductor layer and an active layer disposed therebetween, a passivation layer disposed on the light emitting structure, and a second electrode layer disposed under the light emitting structure. The light emitting structure may include a rounding semiconductor layer in which an upper surface thereof is partially rounded.

### CROSS-REFERENCE TO RELATED APPLICATION

Pursuant to 35 U.S.C. § 119(a), this application claims the benefit of an earlier filing date of and the right of priority to PCT Application No. PCT/KR2022/011240, filed on Jul. 29, 2022, the entire contents of which are hereby expressly incorporated by reference into the present application.

### BACKGROUND OF THE DISCLOSURE

### 1. Field of the Disclosure

Embodiment relates to a semiconductor light emitting device for a display pixel and a display device including the same.

### 2. Discussion of the Related Art

Large-area displays include liquid crystal displays (LCDs), OLED displays, and Micro-LED displays.

The micro-LED display is a display using micro-LED, which is a semiconductor light emitting device having a diameter or cross-sectional area of 100 μm or less, as a display device.

Micro-LED display has excellent performance in many characteristics such as contrast ratio, response speed, color reproduction rate, viewing angle, brightness, resolution, lifespan, luminous efficiency and luminance because it uses micro-LED, which is a semiconductor light emitting device, as a display device.

In particular, micro-LED displays can separate and combine screens in a modular manner, so the micro-LED display has the advantage of freely adjusting the size or resolution and the advantage of being able to implement a flexible display.

However, there is a technical problem in that it is difficult to quickly and accurately transfer the semiconductor light emitting device to the display panel because more than millions of semiconductor light emitting devices are required for a large micro-LED display.

Transfer technologies that have been recently developed include a pick and place process, a laser lift-off method, or a self-assembly method.

Among these, the self-assembly method is a method in which a semiconductor light emitting device finds an assembly position in a fluid by itself, and is an advantageous method for implement a large-screen display device.

Recently, although a micro-LED structure suitable for self-assembly has been proposed in U.S. Pat. No. 9,825,202, etc., research on a technology for manufacturing a display through self-assembly of micro-LEDs is still insufficient.

In particular, in the case of quickly transferring millions or more semiconductor light emitting devices to a large display in the prior art, although the transfer speed can be improved, there is a technical problem in that the transfer error rate can be increased and the transfer yield is lowered.

On the other hand, in related technologies, a self-assembly type transfer process using dielectrophoresis (DEP) has been attempted, but there is a problem in that the self-assembly rate is low due to the non-uniformity of the DEP force.

On the other hand, the self-assembly method using DEP force of internal technology includes the step of first moving the LED chip to the assembly hole area with the magnetic force of the magnet, the step of assembling the LED chip in the assembly hole with DEP force by applying alternating current to the assembly wiring.

By the way, since the LED chip has an n-type semiconductor layer and a p-type semiconductor layer on the upper and lower sides, and the n-type electrode and the p-type electrode are disposed, it is very important to assemble the LED chip into the assembly hole while maintaining the vertical direction of the LED chip. This is because electrical disconnection defects can occur in a subsequent wiring process when the LED chip is assembled with the direction tilted or reversed by 180 degrees.

However, according to internal research, it has been studied as a difficult problem to directionally control LED chips during self-assembly moving in a fluid, and a solution to this problem is critically required.

Also, in the related art, there is a problem in that the lighting rate is lowered because the electrical contact characteristics between the electrodes of the self-assembled LED chip and the panel electrodes are lowered.

### SUMMARY OF THE DISCLOSURE

One of the technical problems of the embodiment is to solve the problem of low self-assembly rate due to non-uniformity of DEP force in the self-assembly method using dielectrophoresis (DEP).

Also, one of the technical problems of the embodiment is to solve the problem of controlling the LED chip in a directionally direction in a self-assembly method using DEP.

Also, one of the technical problems of the embodiment is to solve the problem that the lighting rate is lowered due to the lowering of the electrical contact characteristics between the electrode of the self-assembled LED chip and the predetermined panel electrode.

The technical problems of the embodiment are not limited to those described in this section, and include those that can be understood throughout the specification.

The semiconductor light emitting device for display pixels according to the embodiment can include a light emitting structure including a first conductivity type semiconductor layer, a second conductivity type semiconductor layer and an active layer disposed therebetween, a passivation layer disposed on the light emitting structure and a second electrode layer disposed under the light emitting structure

The light emitting structure can include a rounding semiconductor layer in which an upper surface thereof is partially rounded.

The light emitting structure can include the rounded semiconductor layer on a side surface of a portion of an upper portion of the first conductivity type semiconductor layer.

The light emitting structure can include the rounded semiconductor layer on a side surface and a portion of an upper portion of the first conductivity type semiconductor layer.

The light emitting structure can further include a protruding semiconductor layer extending further in a horizontal direction on both sides of the round semiconductor layer than side surfaces of the round semiconductor layer.

The protruding semiconductor layer can include the first conductivity-type semiconductor layer, the active layer, and the second conductivity-type semiconductor layer.

The horizontal width of the active layer can be formed to correspond to the maximum horizontal width of the light emitting structure.

The second electrode layer can include a light-transmitting electrode layer disposed on the light emitting structure.

The second electrode layer can include a reflective layer disposed on the light-transmitting electrode layer, a magnetic layer disposed on the reflective layer, and an adhesive layer disposed on the magnetic layer.

A horizontal width of the protruding semiconductor layer can be the same as a horizontal width of the second electrode layer.

The surface of the light-transmitting electrode layer may be hydrophilic.

The light-transmitting electrode layer can be treated with O2 plasma or Ar plasma.

Also, the display device including the semiconductor light emitting device according to the embodiment can include any one of the semiconductor light emitting devices for display pixels.

According to the semiconductor light emitting device and the display device including the same according to the embodiment, in the self-assembly step, the lower semiconductor layer and the lower electrode of the LED chip can be formed to have a wider width than the upper semiconductor layer. Accordingly, according to the embodiment, the DEP force is formed relatively large on the lower electrode plate side, so that the assembly direction of the LED chips can be controlled to achieve a technical effect of enabling proper assembly.

For example, according to the embodiment, since the semiconductor light emitting device has a protruding semiconductor layer 110P, and a larger DEP force is applied to the protruding semiconductor layer 110P, there is a special technical effect of being able to control the direction of the second conductivity type semiconductor layer 113 in the direction of the assembly electrodes 310 and 320.

Also, for example, in the semiconductor light emitting device 100 according to the embodiment, the horizontal width of the second electrode layer 130 can be formed to be large to correspond to the horizontal width of the protruding semiconductor layer 110P. Accordingly, according to the display device according to the embodiment, in the self-assembly step, the lower semiconductor layer of the LED chip and the second electrode layer 130 serving as the lower electrode can be formed to have a wider width than the upper semiconductor layer. Therefore, according to the embodiment, the DEP force is formed relatively large on the side of the second electrode layer 130, which is the lower electrode plate, so that there is a special technical effect that can be assembled by controlling the assembly direction of the LED chips.

Also, according to the embodiment, the light extraction efficiency is improved by preventing total reflection of light emitted by the dome-shaped upper semiconductor layer after self-assembly, also, there is a complex technical effect of improving electrical characteristics by increasing the electrical contact area at the end of the display panel by the wide lower electrode plate.

For example, as the semiconductor light emitting device according to the embodiment includes a dome-shaped round semiconductor layer 110R, after self-assembly, total reflection of light emitted by the dome-shaped upper rounding semiconductor layer 110R is prevented, thereby improving light extraction efficiency. Also, there is a complex technical effect of improving electrical characteristics by increasing the electrical contact area at the display panel end by the second electrode layer 130, which is a wide lower electrode plate.

Also, as the semiconductor light emitting device according to the embodiment includes a dome-shaped round semiconductor layer 110R and the active layer 112 exists up to a region where the horizontal width of the active layer 112 corresponds to the horizontal width of the protruding semiconductor layer 110P, which is the maximum horizontal width of the semiconductor light emitting device, the entire chip size can be a light emitting area, and thus, the light emitting area is wider than that of conventional chips, and light efficiency is remarkably improved.

According to the embodiment, even if the rounding semiconductor layer 110R is located in the assembly hole 340H toward the assembly electrode during the self-assembly process, since the area corresponding to the assembly electrode is small and the effect of the electric field is weak, even if it enters the assembly hole, it comes out immediately, and assembly defects can be prevented.

Also, according to the embodiment, the frictional force between the semiconductor light emitting device having the rounding semiconductor layer 110R and the assembly substrate is low, so that the light emitting device chip moves very fast, and the assembly speed can be increased.

Also, according to the embodiment, in the self-assembly method using dielectrophoresis (DEP), there is a technical effect that can solve the problem of low self-assembly rate due to non-uniformity of DEP force.

For example, since the light-transmitting electrode provided in the light emitting device chip in the embodiment serves as a dielectric film according to its dielectric constant, there is a different and special technical effect that can improve the assembly rate by improving the DEP force.

Also, the light emitting device to which the embodiment is applied has a technical effect of remarkably improving the assembly rate of the light emitting device chip in the assembly hole by evenly distributing the DEP force at the bottom of the light emitting device chip due to the lower electrode layer having a flat surface characteristic due to the light-transmitting electrode layer.

Also, according to the embodiment, there is a technical effect that can solve the problem that the lighting rate is lowered due to the lowering of the electrical contact characteristics between the electrode of the self-assembled light emitting device and the predetermined panel electrode.

For example, according to the embodiment, a light-transmitting electrode layer is formed between the semiconductor light emitting device (chip) epitaxial layer (GaN) and the lower bonding metal, thereby significantly improving the surface morphology of the back bonding metal. Accordingly, according to the embodiment, the contact characteristics between the rear metal of the light emitting element and the panel wiring are remarkably improved, thereby having a technical effect of solving lighting defects.

The technical effects of the embodiments are not limited to those described in this section, and include those that can be understood throughout the specification.

### BRIEF DESCRIPTION OF THE DRAWINGS

FIG. 1 is an exemplary view of a living room of a house in which a display device according to an embodiment is disposed.

FIG. 2 is a block diagram schematically showing a display device according to an embodiment.

FIG. 3 is a circuit diagram showing an example of a pixel of FIG. 2.

FIG. 4 is an enlarged view of a first panel area in the display device of FIG. 1.

FIG. 5 is a cross-sectional view taken along line B1-B2 in area A2 of FIG. 4.

FIG. 6 is an exemplary view in which a light emitting device according to an embodiment is assembled to a substrate by a self-assembly method.

FIGS. 7A to 7D are pictures according to the internal technology related to the display panel.

FIG. 8 is a cross-sectional view of a display device according to an embodiment.

FIG. 8 is a cross-sectional view of the display device 300 according to the first embodiment.

FIG. 9 is a cross-sectional view of the first semiconductor light emitting device 100 in the display device according to the first embodiment.

FIG. 10 is a cross-sectional view of a display device 302 according to a second embodiment.

FIG. 11 is a cross-sectional view of the second semiconductor light emitting element 102 in the display device according to the second embodiment.

FIGS. 12A and 12B are data for a micro LED display according to a second embodiment.

### DETAILED DESCRIPTION OF THE EMBODIMENTS

Hereinafter, embodiments disclosed in the present description will be described in detail with reference to the accompanying drawings. The suffixes ‘module’ and ‘part’ for components used in the following description are given or mixed in consideration of ease of specification, and do not have a meaning or role distinct from each other by themselves. Also, the accompanying drawings are provided for easy understanding of the embodiments disclosed in the present specification, and the technical ideas disclosed in the present specification are not limited by the accompanying drawings. Also, when an element, such as a layer, area, or substrate, is referred to as being ‘on’ another component, this includes that it is directly on the other element or there can be other intermediate elements in between.

The display device described in this specification can include a digital TV, a mobile phone, a smart phone, a laptop computer, a digital broadcasting terminal, a personal digital assistant (PDA), a portable multimedia player (PMP), a navigation, a Slate PC, a Tablet PC, an Ultra-Book, a desktop computer, and the like. However, the configuration according to the embodiment described in this specification can be applied to a device capable of displaying even a new product type to be developed in the future.

Hereinafter, a light emitting device and a display device including the light emitting device according to the embodiment will be described.

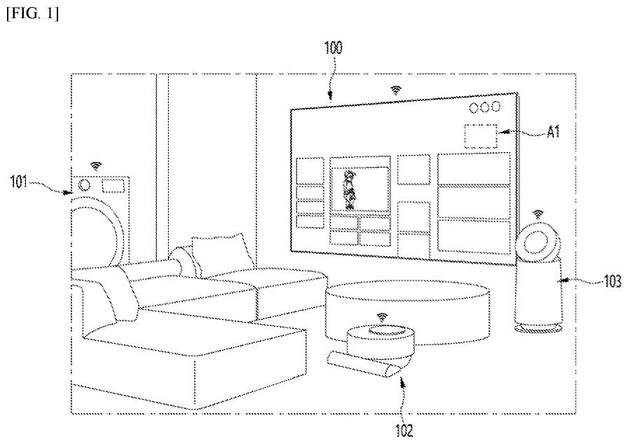

FIG. 1 shows a living room of a house in which a display device 100 according to an embodiment is disposed.

The display device 100 of the embodiment can display the status of various electronic products such as the washing machine 101, the robot cleaner 102, and the air purifier 103, and communicate with each electronic product based on IOT, and can control each electronic product based on the user's setting data.v

The display apparatus 100 according to the embodiment can include a flexible display manufactured on a thin and flexible substrate. The flexible display can be bent or rolled like paper while maintaining the characteristics of a conventional flat panel display.

In the flexible display, visual information can be implemented by independently controlling light emission of unit pixels arranged in a matrix form. A unit pixel means a minimum unit for realizing one color. The unit pixel of the flexible display can be implemented by a light emitting device. In an embodiment, the light emitting device can be a Micro-LED or a Nano-LED, but is not limited thereto.

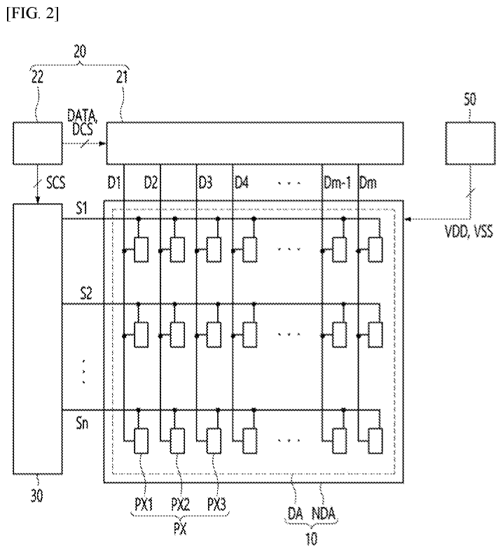

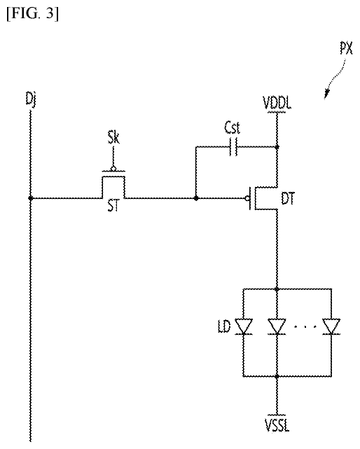

Next, FIG. 2 is a block diagram schematically showing a display device according to an embodiment, and FIG. 3 is a circuit diagram showing an example of the pixel of FIG. 2.

Referring to FIGS. 2 and 3, the display device according to the embodiment can include a display panel 10, a driving circuit 20, a scan driving unit 30, and a power supply circuit 50.

The display device 100 according to the embodiment can drive the light emitting device using an active matrix (AM) method or a passive matrix (PM, passive matrix) method.

The driving circuit 20 can include a data driving unit 21 and a timing control unit 22.

The display panel 10 can be divided into a display area DA and a non-display area NDA disposed around the display area DA. The display area DA is an area in which pixels PX are formed to display an image. The display panel 10 can include data lines (D1 to Dm, m is an integer greater than or equal to 2), scan lines crossing the data lines D1 to Dm (S1 to Sn, n is an integer greater than or equal to 2), the high-potential voltage line supplied with the high-voltage, the low-potential voltage line supplied with the low-potential voltage, and the pixels PX connected to the data lines D1 to Dm and the scan lines S1 to Sn can be included.

Each of the pixels PX can include a first sub-pixel PX1, a second sub-pixel PX2, and a third sub-pixel PX3. The first sub-pixel PX1 emits a first color light of a first wavelength, the second sub-pixel PX2 emits a second color light of a second wavelength, and the third sub-pixel PX3 emits a third color light of a wavelength can be emitted. The first color light can be red light, the second color light can be green light, and the third color light can be blue light, but is not limited thereto. Also, although it is illustrated that each of the pixels PX can include three sub-pixels in FIG. 2, the present invention is not limited thereto. That is, each of the pixels PX can include four or more sub-pixels.

Each of the first sub-pixel PX1, the second sub-pixel PX2, and the third sub-pixel PX3 can connected to at least one of the data lines D1 to Dm, and at least one of the scan lines S1 to Sn, and a high potential voltage line. As shown in FIG. 3, the first sub-pixel PX1 can include the light emitting devices LD, plurality of transistors for supplying current to the light emitting devices LD, and at least one capacitor Cst.

Although not shown in the drawing, each of the first sub-pixel PX1, the second sub-pixel PX2, and the third sub-pixel PX3 can include only one light emitting device LD and at least one capacitor Cst.

Each of the light emitting devices LD may be a semiconductor light emitting diode including a first electrode, a plurality of conductivity type semiconductor layers, and a second electrode. Here, the first electrode can be an anode electrode and the second electrode can be a cathode electrode, but the present invention is not limited thereto.

Referring to FIG. 3, the plurality of transistors can include a driving transistor DT for supplying current to the light emitting devices LD, and a scan transistor ST for supplying a data voltage to the gate electrode of the driving transistor DT. The driving transistor DT can include a gate electrode connected to the source electrode of the scan transistor ST, a source electrode connected to a high potential voltage line to which a high potential voltage is applied, and a drain electrode connected to first electrodes of the light emitting devices LD. The scan transistor ST can include a gate electrode connected to the scan line Sk, where k is an integer satisfying 1≤k≤n, a source electrode connected to the gate electrode of the driving transistor DT, and a drain electrode connected to data lines Dj, where j is integer satisfying 1≤j≤m.

The capacitor Cst is formed between the gate electrode and the source electrode of the driving transistor DT. The storage capacitor Cst can charge a difference between the gate voltage and the source voltage of the driving transistor DT.

The driving transistor DT and the scan transistor ST can be formed of a thin film transistor. Also, although the driving transistor DT and the scan transistor ST have been mainly described in FIG. 3 as being formed of a P-type MOSFET (Metal Oxide Semiconductor Field Effect Transistor), the present invention is not limited thereto. The driving transistor DT and the scan transistor ST can be formed of an N-type MOSFET. In this case, the positions of the source electrode and the drain electrode of each of the driving transistor DT and the scan transistor ST can be changed.

Also, in FIG. 3 has been illustrated each of the first sub-pixel PX1, the second sub-pixel PX2, and the third sub-pixel PX3 can include one driving transistor DT, one scan transistor ST, and 2T1C (2 Transistor-1 capacitor) having a capacitor Cst, but the present invention is not limited thereto. Each of the first sub-pixel PX1, the second sub-pixel PX2, and the third sub-pixel PX3 can include a plurality of scan transistors ST and a plurality of capacitors Cst.

Referring back to FIG. 2, the driving circuit 20 outputs signals and voltages for driving the display panel 10. To this end, the driving circuit 20 can include a data driver 21 and a timing controller 22.

The data driver 21 receives digital video data DATA and a source control signal DCS from the timing controller 22. The data driver 21 converts the digital video data DATA into analog data voltages according to the source control signal DCS and supplies them to the data lines D1 to Dm of the display panel 10.

The timing controller 22 receives digital video data DATA and timing signals from the host system. The timing signals can include a vertical sync signal, a horizontal sync signal, a data enable signal, and a dot clock. The host system may be an application processor of a smartphone or tablet PC, a monitor, or a system-on-chip of a TV.

The scan driver 30 receives the scan control signal SCS from the timing controller 22. The scan driver 30 generates scan signals according to the scan control signal SCS and supplies them to the scan lines S1 to Sn of the display panel 10. The scan driver 30 can include a plurality of transistors and can be formed in the non-display area NDA of the display panel 10. Also, the scan driver 30 can be formed of an integrated circuit, and in this case, can be mounted on a gate flexible film attached to the other side of the display panel 10.

The power supply circuit 50 generates a high potential voltage VDD and a low potential voltage VSS for driving the light emitting devices LD of the display panel 10 from the main power source, and the power supply circuit can supply VDD and VSS to the high-potential voltage line and the low-potential voltage line of the display panel 10. Also, the power supply circuit 50 can generate and supply driving voltages for driving the driving circuit 20 and the scan driving unit 30 from the main power.

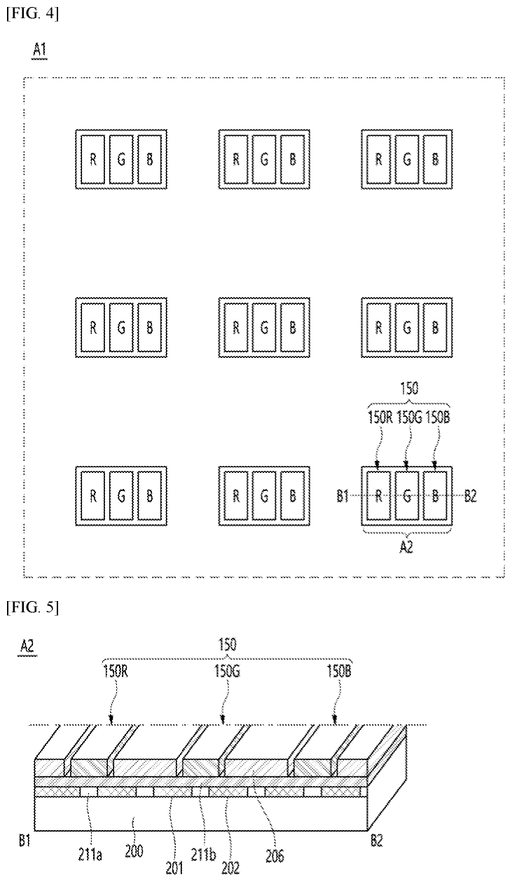

Next, FIG. 4 is an enlarged view of the first panel area A1 in the display device of FIG. 1.

Referring to FIG. 4, the display device 100 according to the embodiment can be manufactured by mechanically and electrically connecting a plurality of panel areas such as the first panel area A1 by tiling.

The first panel area A1 can include a plurality of light emitting devices 150 arranged for each unit pixel (PX in FIG. 2).

For example, the unit pixel PX can include a first sub-pixel PX1, a second sub-pixel PX2, and a third sub-pixel PX3. For example, a plurality of red light-emitting devices 150R are disposed in the first sub-pixel PX1, a plurality of green light-emitting devices 150G are disposed in the second sub-pixel PX2, and a plurality of blue light-emitting devices 150B are disposed in the third sub-pixel PX3. The unit pixel PX can further include a fourth sub-pixel in which a light emitting device is not disposed, but is not limited thereto. Meanwhile, the light emitting device 150 may be the semiconductor light emitting device.

Next, FIG. 5 is a cross-sectional view taken along line B1-B2 of area A2 of FIG. 4.

Referring to FIG. 5, the display device 100 of the embodiment can include a substrate 200, wirings 201 and 202 spaced apart from each other, a first insulating layer 211a, a second insulating layer 211b, a third insulating layer 206 and a plurality of light emitting devices 150.

The assembly line can include a first assembly line 201 and a second assembly line 202 spaced apart from each other. The first assembling wire 201 and the second assembling wire 202 can be provided to generate dielectrophoretic force for assembling the light emitting device 150. Also, the first assembly line 201 and the second assembly line 202 can be electrically connected to the electrode of the light emitting device to function as electrodes of a display panel.

The assembly wirings 201 and 202 can be formed of a transparent electrode (ITO) or include a metal material having excellent electrical conductivity. For example, the assembly wirings 201 and 202 can be formed at least one of titanium (Ti), chromium (Cr), nickel (Ni), aluminum (Al), platinum (Pt), gold (Au), tungsten (W), molybdenum (Mo) or an alloy thereof.

A first insulating layer 211a can be disposed between the first assembly wiring 201 and the assembly second wiring 202, and a second insulating layer 211b can be disposed on the first assembly wiring 201 and the second wiring 202. The first insulating layer 211a and the second insulating layer 211b can be an oxide film, a nitride film, or the like, but are not limited thereto.

The light emitting device 150 can include a red light emitting device 150R, a green light emitting device 150G, and a blue light emitting device 150B0 to form a sub-pixel, respectively, but is not limited thereto. The light emitting device 150 can include a red phosphor and a green phosphor to implement red and green, respectively.

The substrate 200 can be formed of glass or polyimide. Also, the substrate 200 can include a flexible material such as polyethylene naphthalate (PEN) or polyethylene terephthalate (PET). Also, the substrate 200 can be a light-transmitting material, but is not limited thereto.

The third insulating layer 206 can include an insulating and flexible material such as polyimide, PEN, or PET, and can be formed integrally with the substrate 200 to form a single substrate.

The third insulating layer 206 can be a conductive adhesive layer having adhesiveness and conductivity, and the conductive adhesive layer can be flexible to enable a flexible function of the display device. For example, the third insulating layer 206 can be an anisotropy conductive film (ACF) or a conductive adhesive layer such as an anisotropic conductive medium or a solution containing conductive particles. The conductive adhesive layer can be a layer that is electrically conductive in a direction perpendicular to the thickness but electrically insulating in a direction horizontal to the thickness.

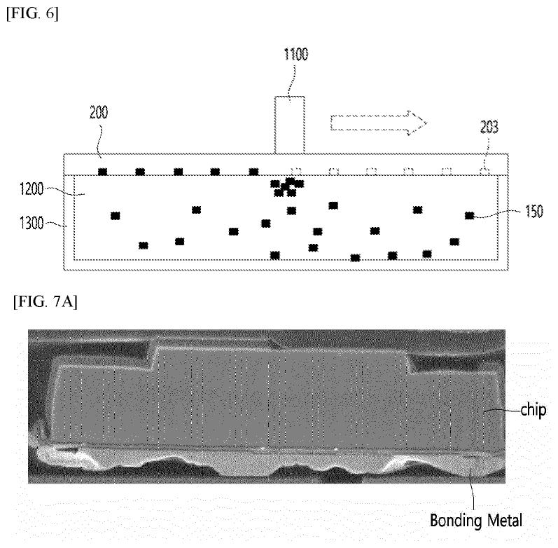

The third insulating layer 206 can include an assembly hole 203 into which the light emitting element 150 is inserted (refer to FIG. 6). Accordingly, during self-assembly, the light emitting device 150 can be easily inserted into the assembly hole 203 of the third insulating layer 206. The assembly hole 203 can be called an insertion hole, a fixing hole, an alignment hole, or the like.

The distance between the assembly wirings 201 and 202 is smaller than the width of the light emitting element 150 and the width of the assembly hole 203, so that the assembly position of the light emitting element 150 using an electric field can be more precisely fixed.

A third insulating layer 206 is formed on the first and second wirings 201 and 202 to protect the first and second wirings 201 and 202 from the fluid 1200, and the third insulating layer 206 is can prevent leakage of current flowing through the two wirings 201 and 202. The third insulating layer 206 can be formed of a single layer or multiple layers of an inorganic insulator such as silica or alumina or an organic insulator.

Also, the third insulating layer 206 can include an insulating and flexible material such as polyimide, PEN, PET, etc., and can be formed integrally with the substrate 200 to form a single substrate.

The third insulating layer 206 can be an adhesive insulating layer or a conductive adhesive layer having conductivity. The third insulating layer 206 is ductile and can enable a flexible function of the display device.

The third insulating layer 206 has a barrier wall, and an assembly hole 203 can be formed by the barrier wall. For example, when the substrate 200 is formed, a portion of the third insulating layer 206 is removed, so that each of the light emitting devices 150 can be assembled into the assembly hole 203 of the third insulating layer 206.

An assembly hole 203 to which the light emitting devices 150 are coupled is formed in the substrate 200, and a surface on which the assembly hole 203 is formed can contact the fluid 1200. The assembly hole 203 can guide an accurate assembly position of the light emitting device 150.

Meanwhile, the assembly hole 203 can have a shape and size corresponding to the shape of the light emitting device 150 to be assembled at the corresponding position. Accordingly, it is possible to prevent assembly of another light emitting element or a plurality of light emitting elements into the assembly hole 203.

FIG. 6 is a view showing an example in which a light emitting device according to an embodiment is assembled to a substrate by a self-assembly method, and the self-assembly method of the light emitting device will be described with reference to the drawings.

The substrate 200 can be a panel substrate of a display device. In the following description, the substrate 200 will be described as a panel substrate of a display device, but the embodiment is not limited thereto.

Referring to FIG. 6, a plurality of light emitting devices 150 can be put into a chamber 1300 filled with a fluid 1200. The fluid 1200 can be water such as ultrapure water, but is not limited thereto. A chamber can also be called a water bath, container, vessel, or the like.

Thereafter, the substrate 200 can be disposed on the chamber 1300. Depending on the embodiment, the substrate 200 can be introduced into the chamber 1300.

As shown in FIG. 5, a pair of assembly wires 201 and 202 corresponding to each of the light emitting devices 150 to be assembled can be disposed on the substrate 200.

Referring to FIG. 6, after the substrate 200 is disposed, an assembly device 1100 including a magnetic material can move along the substrate 200. As the magnetic material, for example, a magnet or an electromagnet can be used. The assembly device 1100 can move while in contact with the substrate 200 in order to maximize the area of the magnetic field into the fluid 1200. Depending on the embodiment, the assembly device 1100 can include a plurality of magnetic bodies or can include a magnetic body having a size corresponding to that of the substrate 200. In this case, the moving distance of the assembling device 1100 can be limited within a predetermined range.

Due to the magnetic field generated by the assembly device 1100, the light emitting device 150 in the chamber 1300 can move toward the assembly device 1100.

While moving toward the assembly device 1100, the light emitting device 150 can enter the assembly hole 203 by a dielectrophoretic force (DEP force) and come into contact with the substrate 200.

Specifically, the assembled wires 201 and 202 form an electric field by an externally supplied power, and dielectrophoretic force can be formed between the assembled wires 201 and 202 by the electric field. The light emitting element 150 can be fixed to the assembly hole 203 on the substrate 200 by this dielectrophoretic force.

By the electric field applied by the assembly wires 201 and 202 formed on the substrate 200, the light emitting device 150 in contact with the substrate 200 can be prevented from being separated by the movement of the assembly device 1100. According to the examples, since the time required for assembling each of the light emitting devices 150 to the substrate 200 can be drastically reduced by the self-assembly method using the above-described electromagnetic field, a large-area high-pixel display can be realized more quickly and economically.

At this time, a predetermined solder layer (not shown) can be formed between the assembly electrode and the light emitting device 150 assembled on the assembly hole 203 of the substrate 200 to improve the bonding strength of the light emitting device 150.

Next, a molding layer (not shown) can be formed in the assembly hole 203 of the substrate 200. The molding layer can be a light-transmissive resin or a resin containing a reflective material or a scattering material.

Hereinafter, a semiconductor light emitting device display device according to an embodiment for solving technical problems will be described with reference to drawings.

### Embodiment

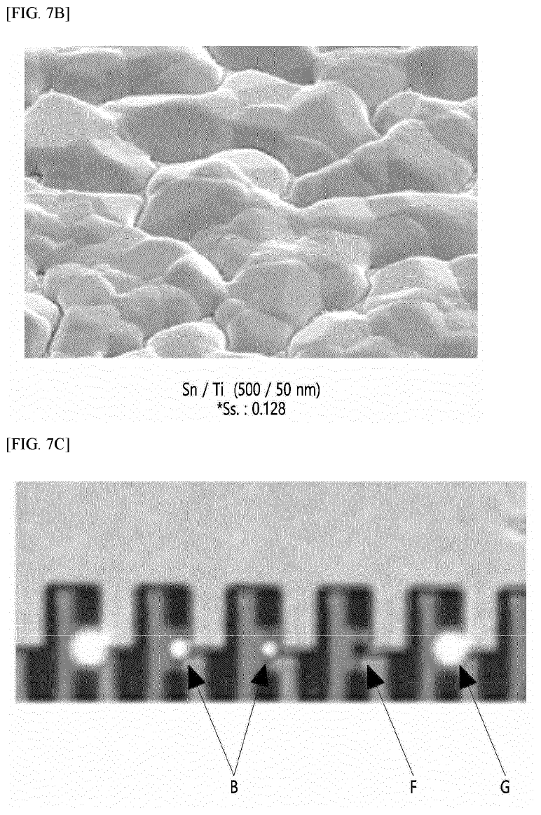

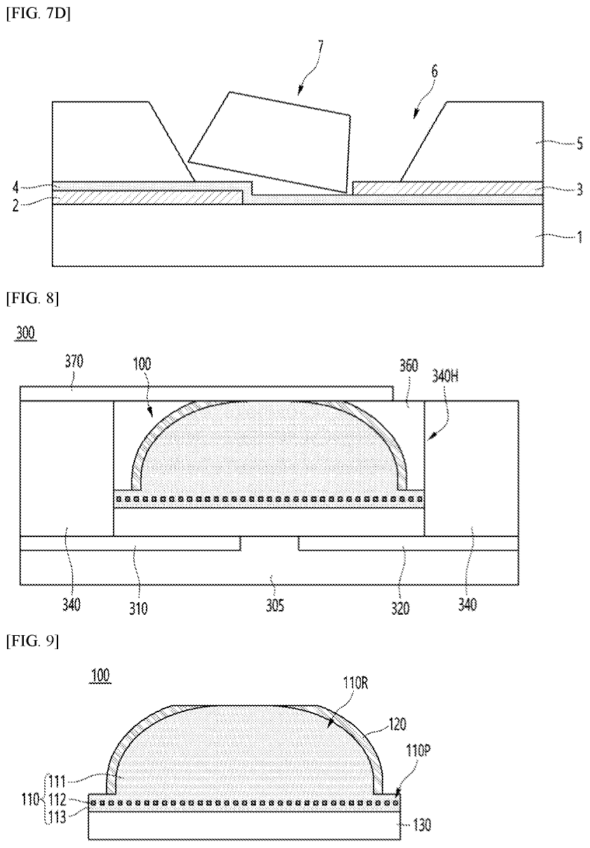

Meanwhile, FIGS. 7A to 7D are data according to an internal technology related to a display panel.

Specifically, FIG. 7A is a photo of a focused ion beam (FIB) of a light emitting device (chip) and bonding metal in a display panel according to an internal technology, and FIG. 7B is a photo of a surface image of a bonding metal in an internal technology.

As shown in FIGS. 7A and 7B, in the semiconductor light emitting device according to the internal technology, the surface morphology of the back bonding metal is not good, and the contact characteristics between the back bonding metal of the light emitting device and the panel wiring are not good, resulting in poor lighting.

For example, FIG. 7C is lighting data in a display panel according to an internal technology.

According to the internal technology, weak lighting (B: Bad) or non-lighting (F: Fail) lighting failure occurs due to poor surface characteristics of the back bonding metal, good lighting (G: Good) has not been achieved, and the lighting rate has been studied at about 93% to 94%.

In the internal technology, materials such as Ti, Cu, Pt, Ag, and Au can be used for the electrode layer of the light emitting device. When a bonding metal of a material such as Sn or In is formed on the electrode layer of such the materials, the surface becomes uneven due to agglomeration.

On the other hand, in the internal technology, the deposition rate was increased to improve the surface characteristics of the bonding metal, but although the agglomeration phenomenon was partially alleviated, another problem was found that the contact force was reduced due to the decrease in grain size as the deposition rate increased. The problem of improving the surface properties of bonding metal was not an easy situation.

Next, FIG. 7D is a diagram illustrating a tilt phenomenon that occurs during self-assembly to an internal technology.

According to the internal technology, the dielectric layer 4 was disposed on the assembly electrodes 2 and 3 on the assembly substrate 1, and self-assembly of the light emitting element 7 was performed in the assembly hole 7 set by the assembly barrier wall 5 by dielectrophoretic force. However, according to the internal technology, the dielectrophoretic force is dispersed or weakened, so that the self-assembly does not work properly and the problem of tilting in the assembly hole 7 has been studied.

Accordingly, one of the technical problems of the embodiment is to solve the problem of low self-assembly rate due to non-uniformity of DEP force in the self-assembly method using dielectrophoresis (DEP).

Also, one of the technical problems of the embodiment is to solve the problem of controlling the LED chip in a direction in a self-assembly method using DEP.

Also, one of the technical problems of the embodiment is to solve the problem that the lighting rate is lowered due to the lowering of the electrical contact characteristics between the electrodes of the self-assembled LED chip and the predetermined panel electrodes.

FIG. 8 is a cross-sectional view of the display device 300 according to the first embodiment, and FIG. 9 is a cross-sectional view of the first semiconductor light emitting device 100 in the display device according to the first embodiment. (In the following description, ‘first embodiment’ will be abbreviated as ‘embodiment’)

Referring to FIG. 8, a display device 300 including a semiconductor light emitting device according to an embodiment can include a substrate 305, first assembly electrode 310, second assembly electrode 320, assembly barrier wall 340, and semiconductor light emitting device 100

Specifically, the display device 300 including the semiconductor light emitting device according to the embodiment can include a substrate 305, a first assembly electrode 310 and a second assembly electrode 320 disposed spaced apart from each other on the substrate 305, an assembly barrier wall 340 including a predetermined assembly hole 340H and disposed on the first and second assembly electrodes 310 and 320 and a semiconductor light emitting device 100 disposed in the assembly hole 340H and electrically connected to the first assembly electrode 310 and the second assembly electrode 320

Also, a display device 300 having a semiconductor light emitting device according to an embodiment can include a light-transmitting resin 360 filling the assembly hole 340H and a second panel wiring 370 electrically connected to the first semiconductor light emitting device 100.

The second panel wiring 370 is a light-transmitting member through which light is transmitted, and can include, for example, ITO. Also, the second panel wiring 370 can include an ohmic metal layer.

According to the semiconductor light emitting device and the display device including the same according to the embodiment, in the self-assembly step, the lower semiconductor layer and the lower electrode of the LED chip can be formed to have a wider width than the upper semiconductor layer. Accordingly, according to the embodiment, the DEP force is formed relatively large on the lower electrode plate side, so that the assembly direction of the LED chips can be controlled to have a technical effect of enabling proper assembly.

Also, according to the embodiment, the light extraction efficiency is improved by preventing total reflection of light emitted by the dome-shaped upper semiconductor layer after self-assembly, also, there is a complex technical effect of improving electrical characteristics by increasing the electrical contact area at the end of the display panel by the wide lower electrode plate.

Also, according to the embodiment, in the self-assembly method using dielectrophoresis (DEP), there is a technical effect that can solve the problem of low self-assembly rate due to non-uniformity of DEP force.

Also, the light emitting device to which the embodiment is applied has a technical effect of remarkably improving the assembly rate of the light emitting device chip in the assembly hole by evenly distributing the DEP force at the bottom of the light emitting device chip due to the lower electrode layer having a flat surface characteristic due to the light-transmitting electrode layer.

Also, according to the embodiment, there is a technical effect that can solve the problem that the lighting rate is lowered due to the lowering of the electrical contact characteristics between the electrode of the self-assembled light emitting device and the predetermined panel electrode.

Hereinafter, while describing the first semiconductor light emitting device 100 according to the embodiment with reference to FIG. 9, the technical features of the applied invention will be described in detail.

Referring to FIG. 9, the first semiconductor light emitting device 100 of the embodiment can be implemented as a vertical type semiconductor light emitting device as shown, but is not limited thereto and a horizontal type light emitting device can be employed.

The first semiconductor light emitting device 100 can include a light emitting structure 110, a second electrode layer 130, and a passivation layer 120.

For example, in the first semiconductor light emitting device 100 can include a second electrode layer 130 disposed on the second conductivity type semiconductor layer 113, and a passivation layer 120 disposed on a portion of the top and side surfaces of the light emitting structure 110

The light emitting structure 110 can include a first conductivity type semiconductor layer 111, a second conductivity type semiconductor layer 113, and an active layer 112 disposed therebetween. The first conductivity-type semiconductor layer 111 can be an n-type semiconductor layer, and the second conductivity-type semiconductor layer 113 can be a p-type semiconductor layer, but is not limited thereto.

The first conductivity-type semiconductor layer 111, the active layer 112, and the second conductivity-type semiconductor layer 113 can be made of a compound semiconductor material. For example, the compound semiconductor material can be a Group 3-5 compound semiconductor material, a Group 2-6 compound material, or the like. For example, the compound semiconductor material can include GaN, InGaN, AlN, AlInN, AlGaN, AlInGaN, InP, GaAs, GaP, GaInP, and the like.

For example, the first conductivity type semiconductor layer 111 can include a first conductivity type dopant, and the second conductivity type semiconductor layer 113 can include a second conductivity type dopant. For example, the first conductivity type dopant can be an n-type dopant such as silicon (Si), and the second conductivity type dopant can be a p-type dopant such as boron (B).

The active layer 112 is a region for generating light, and can generate light having a specific wavelength band according to material properties of the compound semiconductor. That is, the wavelength band can be determined by the energy band gap of the compound semiconductor included in the active layer 112. Accordingly, according to the energy bandgap of the compound semiconductor included in the active layer 112, the semiconductor light emitting device 110 of the embodiment can generate UV light, blue light, green light, and red light.

Next, the second electrode layer 130 can include a metal having excellent electrical conductivity. The second electrode layer 130 can include a bonding metal layer. For example, the second electrode layer 130 can include a bonding metal such as Sn or In, but is not limited thereto. Also, the second electrode layer 130 can further include an adhesive layer (not shown) such as Cr or Ti to enhance adhesion.

The second electrode layer 130 can include a magnetic layer (not shown). The magnetic layer can be provided on the lower side or upper side of the light emitting structure 110. The magnetic layer can include a nickel (Ni) layer, but is not limited thereto.

Next, the passivation layer 120 can be formed of an inorganic insulator such as silica or alumina through PECVD, LPCVD, sputtering deposition, or the like. After the semiconductor light emitting device 100 is assembled to the assembly substrate 200, a partial upper region of the passivation layer 120 can be etched in a manufacturing process of a display device.

One of the technical problems of the embodiment is to solve the problem of low self-assembly rate due to non-uniformity of DEP force in the self-assembly method using dielectrophoresis (DEP).

Also, one of the technical problems of the embodiment is to solve the problem of controlling the LED chip in a direction in a self-assembly method using DEP.

Also, one of the technical problems of the embodiment is to solve the problem that the lighting rate is lowered due to the lowering of the electrical contact characteristics between the electrodes of the self-assembled LED chip and the predetermined panel electrodes.

The first semiconductor light emitting device 100 according to an embodiment for solving the technical problem can include a protruding semiconductor layer 110P and/or a round semiconductor layer 110R.

For example, in the first semiconductor light emitting device 100, an upper portion of the first conductivity-type semiconductor layer 111 can include a rounding semiconductor layer 110R rounded on a side surface.

For example, an upper portion of the first conductivity type semiconductor layer 111 in the first semiconductor light emitting device 100 can include a rounded semiconductor layer 110R.

For example, in the first semiconductor light emitting device 100, an upper portion of the first conductivity-type semiconductor layer 111 can include a rounding semiconductor layer 110R rounded on a side surface and an upper surface.

Also, a portion of the side surface of the first conductivity type semiconductor layer 111 can include a protruding semiconductor layer 110P that extends further in the horizontal direction on both sides than the side surface of the round semiconductor layer 110R.

The passivation layer 120 may not be formed on the protruding semiconductor layer 110P and the first conductivity type semiconductor layer 111 can be exposed, but is not limited thereto.

For example, a passivation layer 120 can also be formed on the protruding semiconductor layer 110P.

The protruding semiconductor layer 110P can include a first conductivity type semiconductor layer 111, a second conductivity type semiconductor layer 113, and an active layer 112 disposed therebetween.

Accordingly, since the horizontal width of the active layer 112 can be secured to a width corresponding to the maximum horizontal width of the semiconductor light emitting device, the luminance can be improved by maximizing the light emitting area.

Also, as the first conductivity type semiconductor layer 111 is disposed on the active layer 112 in the protruding semiconductor layer 110P, there is a technical effect of improving internal light emitting efficiency by minimizing etching damage of the active layer 112.

According to the embodiment, since the lower side of the semiconductor light emitting device 100 receives more DEP force by the protruding semiconductor layer 110P, there is a special technical effect of controlling the vertical direction of the semiconductor light emitting device 100.

For example, when the first semiconductor light emitting device 100 is a vertical light emitting device, the orientation of the first conductivity type semiconductor layer 111 and the second conductivity type semiconductor layer 113 is important in electrical connection with the assembly electrodes 310 and 320.

In the internal technology, when the semiconductor light emitting device is a vertical light emitting device, it is difficult to control the orientation of the first conductivity type semiconductor layer 111 and the second conductivity type semiconductor layer 113. But, according to the embodiment, since the semiconductor light emitting device has a protruding semiconductor layer 110P, and a larger DEP force is applied to the protruding semiconductor layer 110P, there is a special technical effect of being able to control the direction of the second conductivity type semiconductor layer 113 in the direction of the assembly electrodes 310 and 320.

Also, in the semiconductor light emitting device 100 according to the embodiment, the horizontal width of the second electrode layer 130 disposed on the second conductivity type semiconductor layer 113 can be formed to be large to correspond to the horizontal width of the protruding semiconductor layer 110P.

Accordingly, according to the display device according to the embodiment, in the self-assembly step, the lower semiconductor layer of the LED chip and the second electrode layer 130 serving as a lower electrode can be formed to have a wider width than the upper semiconductor layer. Therefore, according to the embodiment, the DEP force is formed relatively large on the side of the second electrode layer 130, which is the lower electrode plate, so that there is a special technical effect that can be assembled by controlling the assembly direction of the LED chip.

Also, as the semiconductor light emitting device according to the embodiment includes a dome-shaped round semiconductor layer 110R, after self-assembly, total reflection of light emitted by the dome-shaped upper rounding semiconductor layer 110R is prevented, thereby improving light extraction efficiency. Also, there is a complex technical effect of improving electrical characteristics by increasing the electrical contact area at the display panel end by the second electrode layer 130, which is a wide lower electrode plate.

Also, as the semiconductor light emitting device according to the embodiment includes a dome-shaped round semiconductor layer 110R and the active layer 112 exists up to a region where the horizontal width of the active layer 112 corresponds to the horizontal width of the protruding semiconductor layer 110P, which is the maximum horizontal width of the semiconductor light emitting device, the entire chip size can be a light emitting area, and thus, the light emitting area is wider than that of conventional chips, and light efficiency is remarkably improved.

According to the embodiment, even if the rounding semiconductor layer 110R is located in the assembly hole 340H toward the assembly electrode during the self-assembly process, since the area corresponding to the assembly electrode is small and the effect of the electric field is weak, even if it enters the assembly hole, it comes out immediately, preventing assembly defects.

Also, according to the embodiment, the frictional force between the semiconductor light emitting device having the rounding semiconductor layer 110R and the assembly substrate is low, so that the light emitting device chip moves very fast, and the assembly speed can be increased.

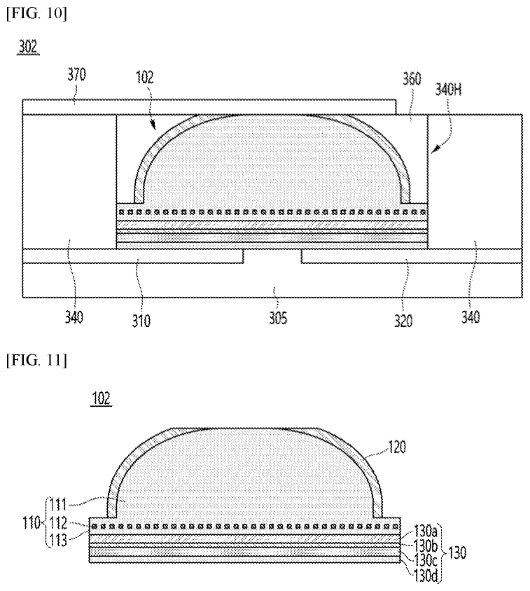

Next, FIG. 10 is a cross-sectional view of the display device 302 according to the second embodiment, and FIG. 11 is a cross-sectional view of the second semiconductor light emitting device 102 in the display device according to the second embodiment.

The display device 302 and the second semiconductor light emitting device 102 according to the second embodiment can adopt the technical features of the display device 300 and the semiconductor light emitting device 100 according to the first embodiment described above, and hereinafter, technical features of the second embodiment will be described with reference to FIG. 11.

Referring to FIG. 11, the second electrode layer 130 can include at least one of a light-transmitting electrode layer 130a, a reflective layer 130b, a magnetic layer 130c, and an adhesive layer 130d.

For example, the second electrode layer 130 can include a light-transmitting electrode layer 130a disposed on the light emitting structure 110.

The light-transmitting electrode layer 130a can include at least one of indium tin oxide (ITO), indium aluminum zinc oxide (IAZO), IZO (indium zinc oxide), IZTO (indium zinc tin oxide), IGZO (indium gallium zinc oxide), IGTO (indium gallium tin oxide), AZO (aluminum zinc oxide), ATO (antimony tin oxide), GZO (gallium zinc oxide), IZON (IZO Nitride), AGZO (Al—Ga ZnO), or IGZO (In—Ga ZnO), but is not limited to these materials.

Also, the second electrode layer 130 can include a reflective layer 130b disposed on the light-transmitting electrode layer 130a. The reflective layer 130b can be any one of Ag, Al, or AgPdCu having good reflectivity.

Also, the second electrode layer 130 can include a magnetic layer 130c such as Ni disposed on the reflective layer 130b.

Also, the second electrode layer 130 can include an adhesive layer 130d disposed on the magnetic layer 130c. The adhesive layer 130d can be a metal having excellent adhesion such as Ti or Cr.

According to the second embodiment, in the self-assembly method using dielectrophoresis (DEP), there is a technical effect of solving the problem of low self-assembly rate due to non-uniformity of DEP force.

For example, since the light-transmitting electrode layer 130a provided on the light emitting device chip in the second embodiment serves as a dielectric film according to its dielectric constant, the second embodiment has a different and special technical effect that can improve the assembly rate by improving the DEP force.

Also, a light emitting device to which the embodiment is applied has a technical effect of remarkably improving the assembly rate of the light emitting device chip in the assembly hole by evenly distributing the DEP force at the bottom of the light emitting device chip due to the lower electrode layer having a flat surface characteristic due to the light-transmitting electrode layer 130a.

Also, according to the embodiment, there is a technical effect that can solve the problem that the lighting rate is lowered due to the lowering of the electrical contact characteristics between the electrode of the self-assembled light emitting device and the predetermined panel electrode.

For example, according to the embodiment, by forming the light-transmitting electrode layer 130a between the epitaxial layer (GaN), which is the light emitting structure 110 of the semiconductor light emitting device (chip), and the lower adhesive layer 130d, there is a technical effect of significantly improving the surface morphology of the back bonding metal. Accordingly, according to the embodiment, the contact characteristics between the rear metal of the light emitting element and the panel wiring are remarkably improved, thereby having a technical effect of solving lighting defects.

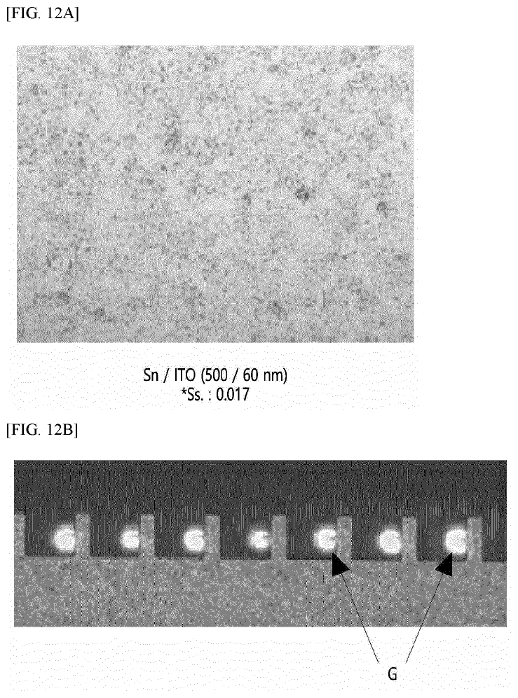

For example, FIGS. 12A and 12B are data for a micro LED display according to the second embodiment.

Specifically, FIG. 12A is an FIB picture of a semiconductor light emitting device applied to a micro-LED display according to an embodiment, and FIG. 12B is a picture of a surface image of a bonding metal in FIG. 12A. FIGS. 12A and 12B are experimental examples in which ITO is used as a material for the light-transmitting electrode layer 130a, but examples are not limited thereto.

According to the embodiment, the light-transmitting electrode layer 130a is formed between the epitaxial layer (GaN) of the semiconductor light emitting device (chip) and the lower bonding metal, thereby having a technical effect of remarkably improving the surface morphology of the back bonding metal. Accordingly, according to the embodiment, the contact characteristics between the rear metal of the light emitting element and the panel wiring are remarkably improved, thereby having a technical effect of solving lighting defects.

For example, FIG. 12B is lighting data in a display panel according to an embodiment. According to the embodiment, poor lighting is prevented by improving the surface characteristics of the back metal, and good lighting (G: Good) is achieved, thereby solving the problem of weak lighting or non-lighting.

In the embodiment, the light-transmissive electrode layer 130a can be formed thinner than the adhesive layer 130d.

For example, the light-transmissive electrode layer 130a can be formed to a thickness of 100 nm or less. Also, the light-transmissive electrode layer 130a can be formed to be 80 nm or less. Also, the light-transmitting electrode layer 130a can be formed to be 60 nm or less.

Also, the light-transmitting electrode layer 130a can be formed to be 10 nm or more. Also, the light-transmitting electrode layer 130a can be formed to be 20 nm or more. Also, the light-transmitting electrode layer 130a can be formed to be 30 nm or more.

According to an internal study, it has been studied that the surface properties of the adhesive layer 130d formed on the light-transmitting electrode layer 130a are significantly improved by making the surface property of the light-transmitting electrode layer 130a hydrophilic, so that it is uniformly formed without agglomeration.

Since the light-transmitting electrode layer 130a according to the embodiment has a higher melting point than that of the bonding metal, there is a special technical effect that does not cause a reliability problem even in the thermal compression process.

In the field of conventional electronic devices using light emitting devices, ITO has been employed as an upper electrode layer of a light emitting device, but it is difficult to employ ITO as a material for a lower electrode layer due to its relatively low conductivity. Also, there was a technical barrier to adopting ITO as a bonding metal material in which the thermocompression process proceeds because the physical property of ITO is weak against impact.

On the other hand, according to the embodiment, by treating the light-transmitting electrode layer 130a with O2 plasma or Ar plasma, it is possible to improve the contact force with the magnetic layer or the Sn solder layer as the lower electrode layer, and there is a technical effect of improving the reliability of the light-transmitting electrode layer 130a. Also O2 plasma or Ar plasma treatment makes the surface of ITO hydrophilic, so that the surface characteristics of the magnetic layer 130c or the adhesive layer 130d formed on the light-transmitting electrode layer 130a are remarkably improved, and there is a technical effect that the magnetic layer 130c or the adhesive layer 130d are uniformly formed without agglomeration.

Specifically, according to the embodiment, after assembling in a self-assembly method, the p-type semiconductor layer and the n-type semiconductor layer of the light emitting device chip are connected to light. At this time, in the conventional internal technology, the basic characteristics of the rear metal (Sn) for lighting are formed unevenly after deposition. Such a conventional chip has a small contact area where the portion connected to the lighting wiring is small, so there are many cases where the light is weak or does not turn on after being turned on.

However, since the vertical chip having a flat structure to which the embodiment is applied is in overall contact with the lower lighting wiring electrode, the electrical contact is excellent and the lighting yield is remarkably improved.

Also, according to the semiconductor light emitting device and the display device including the same according to the embodiment, in the self-assembly method using dielectrophoresis (DEP), there is a technical effect that can solve the problem of low self-assembly rate due to non-uniformity of DEP force.

For example, in the self-assembly method by dielectrophoretic force using electric and magnetic fields in a fluid, the higher the dielectric constant, the greater the DEP force acting on the chip.

Since the light-transmitting electrode provided in the light emitting device chip in the embodiment serves as a dielectric film according to its dielectric constant, there is a different and special technical effect that can improve the assembly rate by improving the DEP force.

Also, in dielectrophoresis, the DEP force is concentrated at the corner, and the bonding metal in the conventional LED chip protrudes unevenly, and the DEP force is biased in one direction, increasing the possibility of tilting the LED chip.

On the other hand, in the light emitting device to which the embodiment is applied has a technical effect of remarkably improving the assembly rate of the light emitting device chip in the assembly hole by evenly distributing the DEP force at the bottom of the light emitting device chip due to the lower electrode layer having a flat surface characteristic due to the light-transmitting electrode layer.

Also, in the conventional internal technology, when the rear metal of the light emitting device chip is placed on top of another metal, it has a lumpy property, so the surface is uneven, and even if it enters the assembly hole, it is easily separated due to the small contact area, resulting in a decrease in assembly rate.

On the other hand, according to the embodiment, by forming the bonding metal formed on the rear surface flat, there is a technical effect that the rear surface of the light emitting device assembled in the assembly hole by the electric field increases the area in which the light emitting element is assembled flatly inside the assembly hole, thereby stabilizing it and improving the assembly rate.

The manufacturing process of the first semiconductor light emitting device 100 and the second semiconductor light emitting device 102 in the following embodiment will be described, and referring to FIG. 11, the second semiconductor light emitting device 102 will be mainly described.

Referring to FIG. 11, a light emitting structure 110 can be formed on a predetermined first substrate (not shown), and a second electrode layer 130 can be formed on the light emitting structure 110.

The first substrate can be a sapphire substrate, but is not limited thereto. An undoped semiconductor layer (not shown) can be formed on the first substrate.

The light emitting structure 110 can include a first conductivity type semiconductor layer 111, an active layer 112, and a second conductivity type semiconductor layer 113. The first conductivity-type semiconductor layer 111 can be an n-type semiconductor layer, and the second conductivity-type semiconductor layer 113 can be a p-type semiconductor layer, but is not limited thereto.

The second electrode layer 130 can include a light-transmitting electrode layer 130a, a reflective layer 130b, a magnetic layer 130c, and an adhesive layer 130d sequentially formed on the light emitting structure 110.

After the light-transmitting electrode layer 130a is formed, the above-described plasma process can be performed. The reflective layer 130b may be any one of Ag, Al, or AgPdCu having good reflectivity.

The adhesive layer 130d may be a metal having excellent adhesion such as Ti or Cr.

Thereafter, a predetermined second substrate (not shown) is bonded to the second electrode layer 130 to perform a front LLO to remove the first substrate, so that the light emitting structure 110 can be formed on the second substrate and disposed in the order of the second conductivity type semiconductor layer, the active layer, and the first conductivity type semiconductor layer.

Thereafter, a first round etch pattern (not shown) can be formed on the exposed first conductivity type semiconductor layer 111 to remove the undoped semiconductor layer and form a dome-shaped round semiconductor layer.

The first round etching pattern can be a PR or SiO2 material, but is not limited thereto, and can be etched with a plasma device. At this time, when forming a PR or SiO2 pattern, if it is made into a dome shape, GaN, a light emitting structure, can also be made in the same shape during plasma etching.

In this case, a protruding semiconductor layer 110P can be formed by etching a portion of the first conductivity-type semiconductor layer 111 until the active layer 112 reaches it.

Next, the semiconductor light emitting device according to the embodiment can be manufactured by depositing the passivation layer 120 on the light emitting structure 110 and removing the second substrate.

According to the semiconductor light emitting device and the display device including the same according to the embodiment, in the self-assembly step, the lower semiconductor layer and the lower electrode of the LED chip can be formed to have a wider width than the upper semiconductor layer. Accordingly, according to the embodiment, the DEP force is formed relatively large on the lower electrode plate side, so that the assembly direction of the LED chips can be controlled to have a technical effect of enabling proper assembly.

Also, according to the embodiment, the light extraction efficiency is improved by preventing total reflection of light emitted by the dome-shaped upper semiconductor layer after self-assembly, also, there is a complex technical effect of improving electrical characteristics by increasing the electrical contact area at the end of the display panel by the wide lower electrode plate.

Also, as the semiconductor light emitting device according to the embodiment includes a dome-shaped round semiconductor layer 110R and the active layer 112 exists up to a region where the horizontal width of the active layer 112 corresponds to the horizontal width of the protruding semiconductor layer 110P, which is the maximum horizontal width of the semiconductor light emitting device, the entire chip size can be a light emitting area, and thus, the light emitting area is wider than that of conventional chips, and light efficiency is remarkably improved.

According to the embodiment, even if the rounding semiconductor layer 110R is located in the assembly hole 340H toward the assembly electrode during the self-assembly process, since the area corresponding to the assembly electrode is small and the effect of the electric field is weak, even if it enters the assembly hole, it comes out immediately, preventing assembly defects.

Also, according to the embodiment, the frictional force between the semiconductor light emitting device having the rounding semiconductor layer 110R and the assembly substrate is low, so that the light emitting device chip moves very fast, and the assembly speed can be increased.

Also, according to the embodiment, in the self-assembly method using dielectrophoresis (DEP), there is a technical effect that can solve the problem of low self-assembly rate due to non-uniformity of DEP force.

Also, the light emitting device to which the embodiment is applied has a technical effect of remarkably improving the assembly rate of the light emitting device chip in the assembly hole by evenly distributing the DEP force at the bottom of the light emitting device chip due to the lower electrode layer having a flat surface characteristic due to the light-transmitting electrode layer.

Also, according to the embodiment, there is a technical effect that can solve the problem that the lighting rate is lowered due to the lowering of the electrical contact characteristics between the electrode of the self-assembled light emitting device and the predetermined panel electrode.

The above detailed description should not be construed as limiting in all respects and should be considered as illustrative. The scope of the embodiments should be determined by reasonable interpretation of the appended claims, and all changes within the equivalent range of the embodiments are included in the scope of the embodiments.

The embodiment can be adopted in the display field for displaying images or information.

The embodiment can be adopted in the display field for displaying images or information using a semiconductor light emitting device.

The embodiment can be adopted in the display field for displaying images or information using micro-level or nano-level semiconductor light emitting devices.

What is claimed is:

1. A semiconductor light emitting device for display pixels comprising:
a light emitting structure including a first conductivity type semiconductor layer, a second conductivity type semiconductor layer, and an active layer disposed therebetween;
a passivation layer disposed on the light emitting structure; and
a second electrode layer disposed under the light emitting structure,
wherein the light emitting structure comprises a rounding semiconductor layer in which an upper surface thereof is partially rounded.

2. The semiconductor light emitting device for display pixels according to claim 1, wherein the light emitting structure comprises the rounded semiconductor layer on a side surface of a portion of an upper portion of the first conductivity type semiconductor layer.

3. The semiconductor light emitting device for display pixels according to claim 1, wherein the light emitting structure comprises the rounded semiconductor layer on a portion of a side surface and an upper surface of the first conductivity type semiconductor layer.

4. The semiconductor light emitting device for display pixels according to claim 1, wherein the light emitting structure further comprises a protruding semiconductor layer that extends further in a horizontal direction on both sides of the round semiconductor layer than side surfaces of the round semiconductor layer.

5. The semiconductor light emitting device for display pixels according to claim 4, wherein the protruding semiconductor layer comprises the first conductivity-type semiconductor layer, the active layer, and the second conductivity-type semiconductor layer.

6. The semiconductor light emitting device for display pixels according to claim 5, wherein the horizontal width of the active layer is formed to correspond to the maximum horizontal width of the light emitting structure.

7. The semiconductor light emitting device for display pixels according to claim 4, wherein the second electrode layer comprises a light-transmitting electrode layer disposed on the light emitting structure.

8. The semiconductor light emitting device for display pixels according to claim 7, wherein the second electrode layer comprises a reflective layer disposed on the light-transmitting electrode layer, a magnetic layer disposed on the reflective layer, and an adhesive layer disposed on the magnetic layer.

9. The semiconductor light emitting device for display pixels according to claim 4, wherein a horizontal width of the protruding semiconductor layer is equal to a horizontal width of the second electrode layer.

10. The semiconductor light emitting device for display pixels according to claim 7, wherein the surface of the light-transmitting electrode layer is hydrophilic.

11. The semiconductor light emitting device for display pixels according to claim 10, wherein the light-transmitting electrode layer is treated with O₂ plasma or Ar plasma.

12. The semiconductor light emitting device for display pixels according to claim 1, wherein the width of the light emitting structure according to the height changes nonlinearly.

13. The semiconductor light emitting device for display pixels according to claim 4, wherein the passivation layer extends from a side surface of the first conductivity-type semiconductor layer to a portion of an upper surface of the protruding semiconductor layer.

14. The semiconductor light emitting device for display pixels according to claim 2, wherein the passivation layer is rounded along a side surface of the first conductivity type semiconductor layer.

15. The semiconductor light emitting device for display pixels according to claim 14, wherein a portion of the upper surface of the first conductivity type semiconductor layer is exposed by the passivation layer.

16. The semiconductor light emitting device for display pixels according to claim 15, wherein an upper surface of the passivation layer and an exposed upper surface of the first conductivity type semiconductor layer are positioned at the same height.

17. A display device including a semiconductor light emitting device comprising:
a substrate;
a plurality of assembled wires spaced apart from each other on the substrate;
a barrier wall disposed on the plurality of assembly wires and having an assembly hole; and
a semiconductor light emitting device disposed in the assembly hole,
wherein the semiconductor light emitting device comprises a light emitting structure including a first conductivity type semiconductor layer, a second conductivity type semiconductor layer, and an active layer disposed therebetween; a passivation layer disposed on the light emitting structure; and a second electrode layer disposed under the light emitting structure, and
wherein the light emitting structure comprises a rounding semiconductor layer in which an upper surface thereof is partially rounded.

18. The display device including the semiconductor light emitting device according to claim 17, wherein the passivation layer is rounded along a side surface of the first conductivity type semiconductor layer.

19. The display device including the semiconductor light emitting device according to claim 17, wherein a portion of the upper surface of the first conductivity type semiconductor layer is exposed by the passivation layer, and
further comprising a panel wiring connected to the exposed first conductivity-type semiconductor layer.

20. The display device including a semiconductor light emitting device according to claim 17, wherein the light emitting structure further comprises a protruding semiconductor layer extending in a horizontal direction on both sides of the round semiconductor layer.
